(19) United States
(12) Patent Application Publication
(10) Pub. No.: US 2024/0195443 A1
(43) Pub. Date: Jun. 13, 2024

(54) METHOD AND APPARATUS FOR LINEARIZING A TRANSMISSION AMPLIFIER OF A TRANSMITTER WITHIN A WIRELESS NETWORK

(71) Applicant: Rohde & Schwarz GmbH & Co. KG, München (DE)

(72) Inventor: Thomas Valten, Unterhaching (DE)

(21) Appl. No.: 18/489,085

(22) Filed: Oct. 18, 2023

(30) Foreign Application Priority Data
Dec. 7, 2022 (EP) 22211968.7

(51) Int. Cl. H04B 1/04

(52) U.S. Cl. CPC H04B 1/0475; H04B 2001/0425

(57) ABSTRACT

A method and apparatus for linearizing a transmission amplifier of a transmitter within a wireless network includes transmitting (S1) a test signal having a preamble and a ramp signal by the transmitter; receiving (S2) the test signal transmitted by at least one receiver; identifying (S3) the transmitter of the test signal on the basis of the preamble; calculating (S4) a pre-distortion characteristic of the transmission amplifier of the identified transmitter on the basis of the distorted ramp signal; transmitting (S5) a retransmission signal which comprises a preamble and the calculated pre-distortion characteristic; and linearizing (S6) the transmission amplifier of the transmitter on the basis of the pre-distortion characteristic.

### CROSS-REFERENCE TO RELATED APPLICATION

This application claims priority to European Patent Application No. 22211968.7, filed on Dec. 7, 2022, the content of which is hereby incorporated by reference in its entirety.

### BACKGROUND OF THE INVENTION

The invention relates to a method and an apparatus for linearizing a transmission amplifier of a transmitter within a wireless network such as a telecommunication network or within a decentralized ad hoc network.

In wireless networks, complex modulation processes can be applied. The resulting transmission signal may comprise a high crest factor where the signal envelope of the transmission signal comprises strong oscillations. In case that such a signal is supplied to a power amplifier, intermodulation products of third order are generated at the output of the power amplifier due to nonlinearities. The nonlinearity is caused by the AM/AM distortion of the transmission characteristic caused by saturation of the power amplifiers. The distortion can be reduced by providing bias currents to the transistors of the power amplifier, however, this reduces the efficiency of the transmission power stage.

A conventional way to increase the efficiency of a transmission power stage is a reduction of the bias currents and to perform a pre-distortion of the input signal of the respective power amplifier to compensate for the compression of the respective power amplifier. Pre-distortion is achieved by multiplication of a complex transmission signal with an inverse characteristic of the respective transmission amplifier. Accordingly, to determine the required inverse characteristic of the transmission amplifier in conventional systems, the transmission signal is coupled to an additional reception signal path where it is demodulated and compared with an ideal undistorted transmission signal. However, this conventional way to determine the inverse characteristics requires the provision of additional hardware within the respective apparatus. This increases the complexity of the circuit, the power consumption and the size of the apparatus.

Accordingly, there is the need to provide a method and apparatus which compensate for unwanted distortions of a transmission amplifier while requiring no additional hardware.

### SUMMARY

The invention provides according to a first aspect a method for linearizing a transmission amplifier of a transmitter within a wireless network comprising the steps of:
transmitting a test signal which comprises a preamble and a ramp signal by the transmitter of the wireless network,
receiving the test signal transmitted by the transmitter of the wireless network by at least one receiver of the wireless network,
identifying the transmitter of the transmitted test signal by the at least one receiver of the wireless network on the basis of the preamble of the test signal received by the respective receiver of the wireless network,
calculating a pre-distortion characteristic of the transmission amplifier of the identified transmitter by the at least one receiver of the wireless network on the basis of the distorted ramp signal of the test signal received by the receiver of the wireless network,
transmitting a retransmission signal which comprises a preamble and the calculated pre-distortion characteristic of the transmission amplifier of the identified transmitter by the receiver of the wireless network to the identified transmitter of the wireless network and linearizing the transmission amplifier of the transmitter on the basis of the pre-distortion characteristic of the retransmission signal received by the transmitter of the wireless network from the receiver of the wireless network.

In a possible embodiment of the method according to the first aspect of the present invention, the preamble of the test signal comprises information used to identify the transmitter by the receiver and used for calculating a channel response, in particular a channel impulse response, of a transmission channel between the transmitter and the receiver of the wireless network.

In a possible embodiment of the method according to the first aspect of the present invention, the preamble of the distorted ramp signal of the test signal received by the receiver of the wireless network is sampled with an oversampling rate.

In a further possible embodiment of the method according to the first aspect of the present invention, the preamble of the ramp signal of the transmitted test signal comprise complex signals.

In a further possible embodiment of the method according to the first aspect of the present invention, the ramp signal of the test signal comprises a linear increasing signal.

In a further possible embodiment of the method according to the first aspect of the present invention, the ramp signal of the test signal comprises a linear decreasing signal.

In a still further possible embodiment of the method according to the first aspect of the present invention, the linear increasing ramp signal or the linear decreasing ramp signal of the transmitted test signal comprises a predefined number of symbols.

In a possible implementation of the method according to the first aspect of the present invention, the linear increasing ramp signal comprises values between an initial value of zero and a final value of one divided by the square root of two (1/sqrt(2)).

In a further possible implementation of the method according to the first aspect of the present invention, the linear decreasing ramp signal comprises an initial value of one divided by the square root of two (1/sqrt(2)) and a final value of zero.

In a still further possible embodiment of the method according to the first aspect of the present invention, values of the pre-distortion characteristic are calculated by the receiver of the wireless network in response to values of a non-distorted linear ramp signal and depending on values of the distorted ramp signal within the test signal received by the receiver of the wireless network.

In a further possible embodiment of the method according to the first aspect of the present invention, the values of the non-distorted linear ramp signal are read from a data memory of the receiver of the wireless network.

In a still further possible embodiment of the method according to the first aspect of the present invention, the values of the distorted ramp signal of the test signal received by the receiver of the wireless network are normalized to a maximum value.

In a further possible embodiment of the method according to the first aspect of the present invention, wherein for determining the values of the pre-distortion characteristic until a predefined threshold value, the values of the pre-distortion characteristic are set to a value of one, and wherein from the predefined threshold value on absolute values of the symbols of the distorted ramp signal are divided by absolute values of the symbols of the linear not distorted ramp signal to calculate the values of the pre-distortion characteristic.

In a further possible embodiment of the method according to the first aspect of the present invention, for linearizing the transmission amplifier each sample value of a complex input signal supplied to the transmission amplifier of the transmitter are multiplied with a value of the pre-distortion characteristic, wherein the index of the value of the pre-distortion characteristic used for multiplication is determined depending on the absolute value of the respective sample value of the complex input signal supplied to the transmission amplifier and depending on a scaling factor.

In a further possible embodiment of the method according to the first aspect of the present invention, the test signal transmitted by the transmitter of the wireless network comprises guard time intervals before and after the linear ramp signal included in the transmitted test signal.

In a further possible embodiment of the method according to the first aspect of the present invention, at least one metric is determined which represents the quality of the test signal received by the receiver of the wireless network.

In a further possible embodiment of the method according to the first aspect of the present invention, the at least one metric representing the quality of the received test signal is determined on the basis of a calculated channel response, in particular channel impulse response, of the test signal received by the receiver of the wireless network.

In a further possible embodiment of the method according to the first aspect of the present invention, a first metric represents the quality of the test signal received by the receiver of the wireless network with respect to multi-path signal propagation.

In a further possible embodiment of the method according to the first aspect of the present invention, the second metric represents the quality of the test signal received by the receiver of the wireless network with respect to a signal-to-noise ratio.

In a further possible embodiment of the method according to the first aspect of the present invention, the pre-distortion characteristic of the transmission amplifier of the identified transmitter is calculated by the at least one receiver of the wireless network on the basis of the distorted ramp signal of the test signal received by the receiver if the first and the second metric indicate a sufficient quality of the test signal received by the receiver of the wireless network.

In a further possible embodiment of the method according to the first aspect of the present invention, a multi-path signal propagation of the transmitted test signal is determined on the basis of spurious signal pulses within the test signal received by the receiver of the wireless network.

In a further possible embodiment of the method according to the first aspect of the present invention, the signal-to-noise ratio of the test signal received by the receiver of the wireless network is determined by division of amplitudes of spurious signal pulses of the channel response of the received test signal by the amplitude of a main pulse of the channel response of the received test signal.

In a further possible embodiment of the method according to the first aspect of the present invention, the channel response of the test signal received by the receiver of the wireless network is determined by multiplication of a vector of the received test signal with a matrix comprising complex symbols of the test signal.

In a still further possible embodiment of the method according to the first aspect of the present invention, the transmission of the retransmission signal is performed by the receiver of the wireless network with a time delay.

In a further possible embodiment of the method according to the first aspect of the present invention, by the time-delayed transmission of the retransmission signal by the receiver of the wireless network a calibration of the wireless network can be performed under control of an access layer of the wireless network.

In a still further possible embodiment of the method according to the first aspect of the present invention, the calculated pre-distortion characteristic included and transported in the retransmission signal is stored in a data memory of the transmitter of the respective wireless network.

The invention further provides according to a further aspect an apparatus for signal transmission within a wireless network comprising the features of claim 23.

The invention provides according to a second aspect an apparatus for signal transmission within a wireless network comprising
a transmitter adapted to transmit a transmission signal amplified by a transmission amplifier of the transmitter to a receiver of at least one other apparatus within the respective wireless network,
a receiver adapted to receive a retransmission signal from a transmitter of another apparatus of the wireless network,
wherein the transmission amplifier of the transmitter of the apparatus is linearized according to a pre-distortion characteristic which is calculated by a processor of another apparatus of the wireless network on the basis of a test signal transmitted by the transmitter of the apparatus, wherein the calculated pre-distortion characteristic is transported within a retransmission signal received by the receiver of the respective apparatus from the other apparatus of the wireless network.

In a possible embodiment of the apparatus according to the second aspect of the present invention, the test signal is transmitted by the transmitter of the apparatus in a test operation mode.

The invention further provides according to a further aspect a wireless network as defined by claim 24.

The invention provides according to the third aspect a wireless network comprising a plurality of apparatuses according to the second aspect of the present invention which are adapted to exchange signals via a bidirectional transmission channel.

In a possible embodiment of the wireless network according to the third aspect of the present invention, the wireless network comprises a decentralized ad hoc network.

In a further possible embodiment of the wireless network according to the third aspect of the present invention, the wireless network comprises a mobile telecommunication network.

In the following, possible embodiments of the different aspects of the present invention are described in more detail with reference to the enclosed figures.

### BRIEF DESCRIPTION

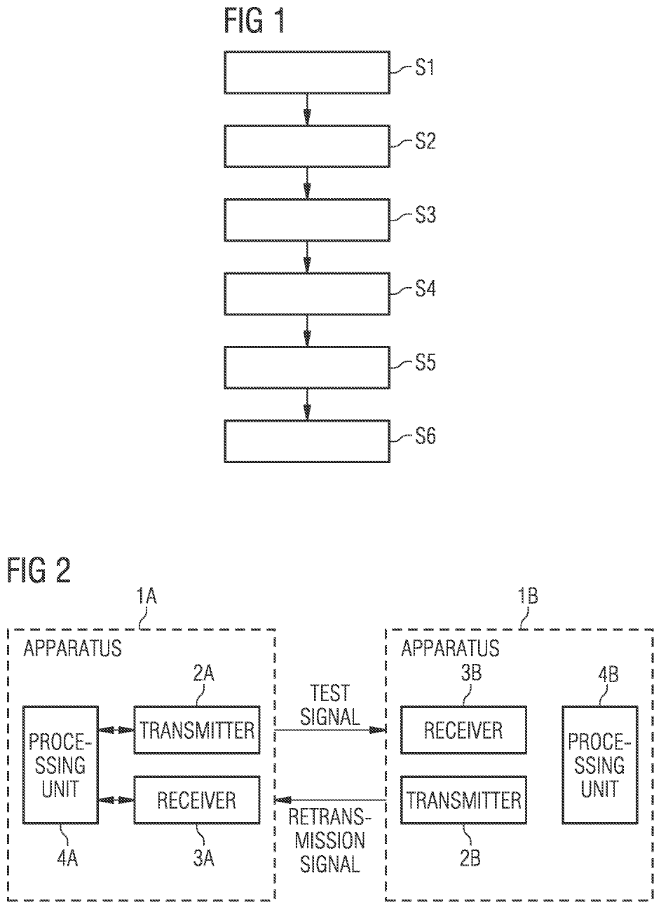

FIG. 1 shows a flowchart for illustrating a possible exemplary embodiment of a method for linearizing a transmission amplifier of a transmitter within a wireless network according to a first aspect of the present invention;

FIG. 2 shows a block diagram for illustrating the communication between two apparatuses according to the second aspect of the present invention using the method for linearizing a transmission amplifier of a transmitter within a wireless network according to the first aspect of the present invention;

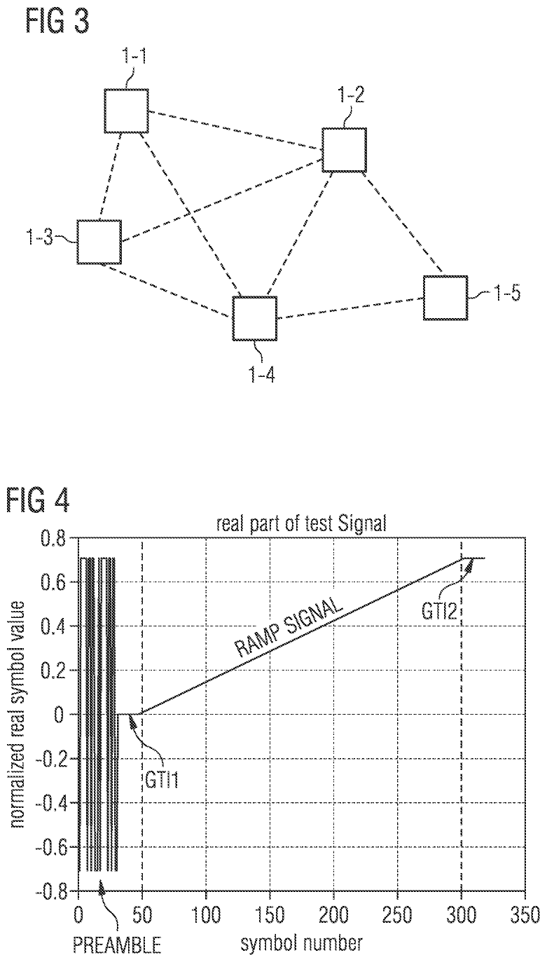

FIG. 3 shows a schematic diagram for illustrating a possible exemplary embodiment of a wireless network implementing a method for linearizing a transmission amplifier of a transmitter within a wireless network as illustrated in FIG. 1;

FIG. 4 illustrates a possible exemplary implementation of a real part of a test signal as employed by the method and apparatus according to the present invention;

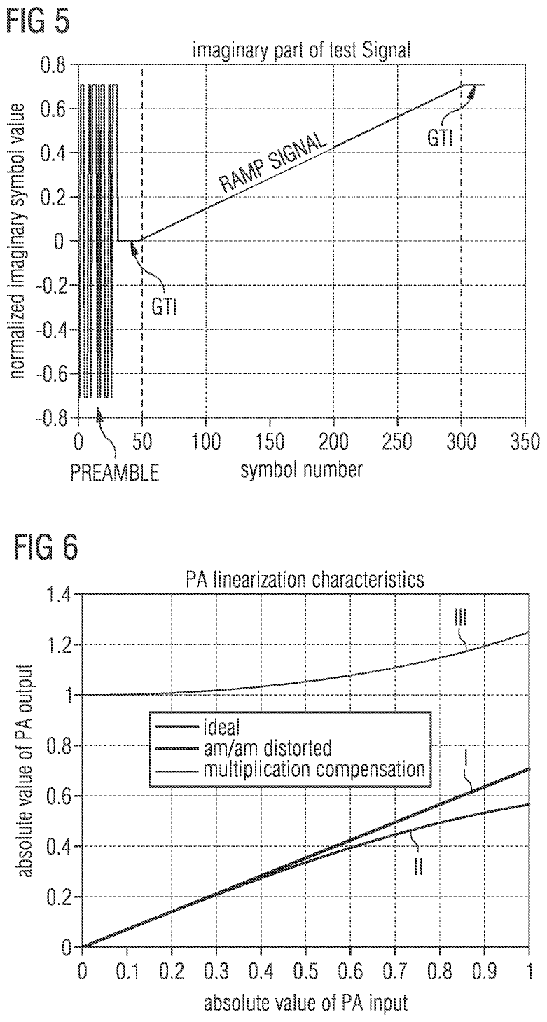

FIG. 5 illustrates a possible exemplary implementation an imaginary part of the test signal as employed by the method and apparatus according to the present invention;

FIG. 6 shows a diagram for illustrating a received test signal with and without AM/AM compression used to provide a multiplied compensation characteristic;

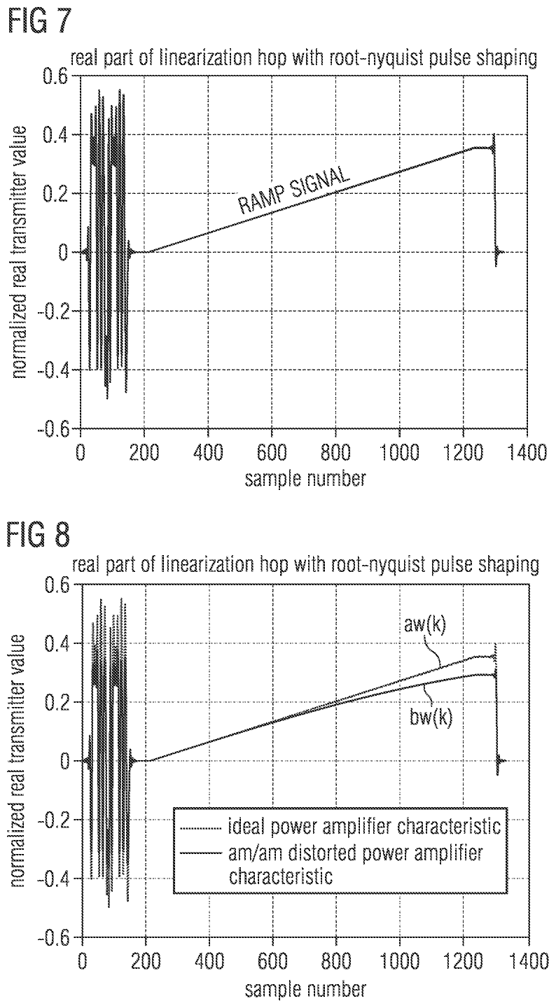

FIG. 7 illustrates a real part of a test signal with root Nyquist pulse shaping;

FIG. 8 illustrates a received test signal without AM/AM distortion and with AM/AM distortion for a real part of a test signal with root Nyquist pulse shaping;

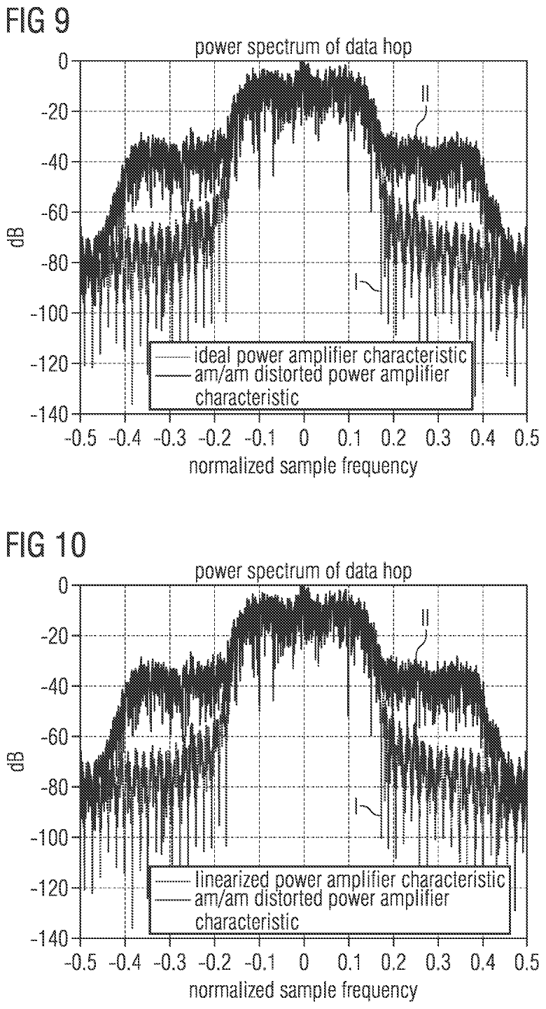

FIG. 9 shows a power spectrum for illustrating the effects of AM/AM distortion in a transmission characteristic as compared to an ideal power amplifier characteristic;

FIG. 10 shows a power spectrum for illustrating a successful linearizing of a power amplifier by using the method according to the present invention;

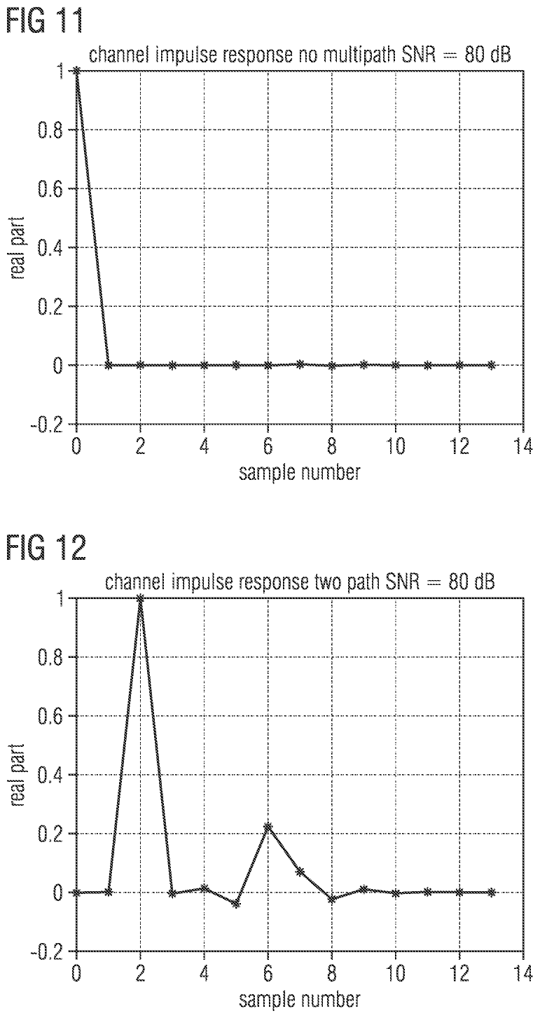

FIGS. 11, 12, 13 illustrate typical channel responses with and without multi-path propagation for different signal-to-noise ratios;

### DETAILED DESCRIPTION

FIG. 1 shows a flowchart of a possible embodiment of a method for linearizing a transmission amplifier of a transmitter within a wireless network according to a first aspect of the present invention.

In the illustrated embodiment of FIG. 1, the method comprises six main steps.

In a first step S1, a test signal is transmitted by a transmitter 2A of a first apparatus 1A of the wireless network as also illustrated in FIG. 2. The transmitted test signal comprises a preamble and a ramp signal as also illustrated in FIGS. 4, 5. The preamble of the signal can identify the respective signal a being a test signal.

The test signal transmitting first apparatus 1A of the wireless network may also be simply referred to as the transmitter. The test signal receiving second apparatus 1B of the wireless network may also be simply referred to as the receiver.

The transmitted test signal is received in step S2 by at least one receiver 3B of a second apparatus 1B of the wireless network. The apparatus can form part of a mobile or immobile network node of the wireless network.

In a further step S3, the transmitting apparatus of the transmitted test signal, i.e. the test signal transmitting first apparatus 1A, is identified by the test signal receiving second apparatus 1B of the wireless network on the basis of the preamble of the test signal received by the receiver 3B of the second apparatus 1B.

In a further step S4, a pre-distortion characteristic of the transmission amplifier of the transmitter of the first apparatus 1A is calculated by a processor 4B of the second apparatus 1B connected to the receiver 3B of the second apparatus 1B on the basis of the distorted ramp signal of the test signal received by the receiver 3B of the second apparatus 1B.

In a further step S5, a retransmission signal is transmitted by a transmitter 2B of the test signal receiving second apparatus 1B back to the identified test signal transmitting first apparatus 1A within the wireless network. The retransmission signal comprises a preamble and the calculated pre-distortion characteristic of the transmission amplifier of the transmitter 2A of the identified test signal transmitting first apparatus 1A. The preamble of the retransmission signal can identify the respective signal as being a retransmission signal.

If a received signal is recognized as being a retransmission signal addressed to the first apparatus 1A the pre-distortion characteristic carried within the received retransmission signal can be extracted automatically and then stored at least temporarily in a table of a local data memory of the first apparatus 1A to be employed by a pre-distortion unit of the first apparatus 1A for pre-distortion of a signal supplied to a transmission amplifier of the transmitter 2A of the first apparatus 1A when sending or broadcasting a signal in the wireless network.

In a final step S6, the transmission amplifier of the transmitter 2A of the test signal transmitting first apparatus 1A is linearized automatically on the basis of the pre-distortion characteristic included and transported in the retransmission signal received by the receiver 3A of the first apparatus 1A of the wireless network from the transmitter 2B of the test signal receiving second apparatus 1B of the wireless network and stored in the local data memory of the first apparatus 1A.

The preamble of the test signal transmitted by the transmitter in step S1 comprises a preamble and a ramp signal. FIG. 4 illustrates the real part of the transmitted test signal.

FIG. 5 illustrates an imaginary part of the transmitted test signal. Accordingly, the transmitted test signal is a complex signal having a real signal part and an imaginary signal part. The transmitted test signal comprises complex symbols as shown in FIGS. 4, 5. The numbers of the symbols of the test signal may vary depending on the use case. As can be seen in FIGS. 4, 5, the test signal comprises at its beginning a preamble which can be used to identify a transmitter of a transmitting first apparatus 1A by a receiver or receiving apparatus 1B receiving the transmitted test signal. The preamble can also be used for calculating a channel response, in particular a channel impulse response h, of a transmission channel between the transmitter 2A and the receiver 3B as shown in FIG. 2. The test signal comprises a ramp signal as shown in FIGS. 4, 5. In the illustrated embodiment of FIGS. 4, 5, the ramp signal comprises a linear increasing signal comprising a predefined number of symbols k. In the illustrated embodiment, the symbols k comprise values between an initial value of zero and a final value of one divided by the square root of two (1/sqrt(2)). On both sides of the ramp signal, guard time intervals GTI can be provided in a possible implementation. The provision of guard time intervals GTI allows transmission filters and reception filters to swing in without influencing the ramp signal. The first guard time interval GTI1 comprises identical symbols k having a value of zero as illustrated in FIGS. 4, 5. The second guard time interval GTI2 comprises identical symbols k having a value of one divided by the square root of two (1/sqrt(2)) as illustrated in FIGS. 4, 5.

In a possible embodiment, the test signal is supplied to a root Nyquist filter for transmission. The root Nyquist filter can comprise a predefined oversampling rate. The resulting transmission signal is illustrated in FIG. 7. As can be seen in FIG. 7, the transmission filter swings in at the beginning and at the end of the guard time. The ramp signal within the received test signal forms the basis for determining the pre-distortion characteristic.

In a possible embodiment, the transmitter or transmitting node 1A of the transmitted test signal can be identified by a receiver 3B of a receiving node or receiving apparatus 1 on the basis of a transmitter identifier extracted from the received test signal. After having identified the transmitter or transmitting node 1A, the pre-distortion characteristic of the transmission amplifier of the identified transmitter 2A is calculated in step S4 by a processor or processing unit 4B of the receiving second apparatus 1B having received the test signal from the transmitting first apparatus 1A. This calculation is performed on the basis of the distorted ramp signal bw(k) of the test signal received by the receiver 3B of the receiving second apparatus 1B as illustrated in FIG. 8. The values dw(k) of the pre-distortion characteristic are calculated by the processing unit 4B of the receiving second apparatus 1B of the wireless network in response to values aw(k) of a non-distorted linear ramp signal and depending on values bw(k) of the distorted ramp signal transported within the test signal and received by the receiver 3B of the second apparatus 1B of the wireless network. In a possible embodiment, the values of the non-distorted linear ramp signal aw(k) can be read from a data memory of the receiving second apparatus 1B of the wireless network. In a possible embodiment, the complex distorted ramp signal having the values bw(k) can be cut on the receiving side from the received sampling values. To avoid scaling problems, the values of the distorted ramp signal bw(k) can be normalized to a maximum value. This can for instance be achieved by division of all complex values by the maximum absolute value of bw(k) (max abs(bw(k))). To achieve a desired resolution of the pre-distortion characteristic, the received distorted ramp signal can be interpolated by a suitable interpolation filter to achieve the required number of sampling values. This also provides an additional suppression of unwanted noise. The linear ramp signal sample values are cut out including both guard time intervals GTI1, GTI2 to guarantee the swinging in of the interpolation filter. On the basis of the known ideal ramp signal values aw(k), it is possible for a processor 4B connected to the receiver 3B to calculate values of the pre-distortion characteristics dw(k). For this purpose, the absolute values of the distorted ramp signal bw(k) and of the known ideal non-distorted linear ramp signal aw(k) are divided. In order that the division does not cause numerical problems for small input values, this division is only performed starting from a predefined threshold value S and the corresponding values of the pre-distortion characteristic are set to a value of one (dw(k)=1). This is admissible since the power amplifiers work at small inputs in a linear manner and do not require any pre-distortion. If the symbol number k is larger than the predefined threshold value S, absolute values abs(bw(k)) of the symbols k of the distorted ramp signal bw(k) are divided by absolute values abs(aw(k)) of the symbols k of the linear non-distorted ramp signal aw(k) to calculate the values dw(k) of the pre-distortion characteristic.

The pre-distortion characteristic calculated in step S4 is transmitted in step S5 within a retransmission signal from a transmitter 2B of the test signal receiving second apparatus 1B of the wireless network back to the identified test signal transmitting first apparatus 1A. Using the retransmitted pre-distortion characteristic, the transmission amplifier of the transmitter 2A of the node 1A having sent the test signals can be linearized on the basis of the received pre-distortion characteristic stored in a data memory of the node 1A. For linearizing the transmission amplifier of the transmitter 2A, each sample value s(k) of a complex input signal supplied to the transmission amplifier of the transmitter 2A is multiplied with a value dw(n) of the re-transmitted and stored pre-distortion characteristic. The index n of the value of the pre-distortion characteristic used for multiplication is determined in a possible embodiment depending on the absolute value of the respective sample value s(k) of the complex input signal supplied to the transmission amplifier of the transmitter 2A and depending on a scaling factor P.

n=round(abs(s(k)·P))

FIG. 6 illustrates the linearization of the transmission amplifier of a transmitter performed in step S6 of the method according to the first aspect of the present invention. Curve I represents the ideal linear increasing ramp signal. Curve II illustrates the received nonlinear characteristic. Curve III represents the pre-distortion characteristic provided by multiplication.

FIG. 9 illustrates the effects of an AM/AM distortion of the transmitter characteristic. The spectrum I illustrates the behavior of a power amplifier without distortion, i.e. an ideal power amplifier characteristic. The spectrum II of FIG. 9 illustrates a power amplifier having AM/AM distortion, i.e. an AM/AM distorted power amplifier characteristic. FIG. 9 shows the intermodulation products at the shoulders of the illustrated spectrum II.

A successful linearization of the transmission amplifier of a transmitter is illustrated in FIG. 10. The spectrum II illustrates a transmission amplifier having AM/AM distortion. The power spectrum I of FIG. 10 illustrates a power amplifier where the input signal supplied to the power amplifier is multiplied with a pre-distortion characteristic dw(k).

To guarantee that the linearization of the transmission amplifier is performed successfully, it is necessary that the test signal is received by the receiver without disturbances. For this reason, the determination of at least one metric M indicating the quality of the received test signal is necessary. In a possible embodiment, the at least one metric representing the quality of the test signal received in step S2 is determined on the basis of a calculated channel impulse response h of the test signal received by the receiver of the wireless network.

In a possible implementation, two metrics M1, M2 can be used. The first metric M1 represents the quality of the test signal received by the receiver of the wireless network with respect to multi-path signal propagation. A second metric M2 represents the quality of the test signal received by the receiver of the wireless network with respect to signal-to-noise ratio SNR.

In a possible embodiment, the pre-distortion characteristic of the transmission amplifier of the identified transmitter is calculated by the at least one receiver of the wireless network on the basis of the distorted ramp signal of the test signal received by the receiver if both determined metrics M1, M2 indicate a sufficient quality of the test signal received by the receiver of the wireless network. If at least one of the determined metrics M1, M2 indicate that the quality of the test signal is not sufficient, the received test signal is not taken into account when calculating the pre-distortion characteristic of the transmission amplifier.

FIGS. 11, 12, 13 illustrate typical channel impulse responses h of a transmission channel between a transmitter and a receiver of a wireless network. FIG. 11 illustrates a channel impulse response h of the transmission channel without multi-path signal propagation and a high signal-to-noise ratio SNR of 80 dB. The resulting metrics allow to calculate a pre-distortion characteristic. As can be seen in FIG. 11, besides the main maximum, no other subordinate maxima are provided which might be caused by multi-path signal propagation. The calculation of the signal-to-noise ratio SNR can be performed such that the power of the main maximum is divided by a sum of the power of all other sample values of the channel impulse response h.

FIG. 12 illustrates a channel impulse response h of a multi-path transmission channel having two paths and a high signal-to-noise ratio SNR. In this case, the metric indicates that a calculation of a pre-distortion characteristic is not feasible. For calculation of the metric, the power of the main maximum and the power of the subordinate maxima can be determined and the ratio between these entities can be calculated. If this ratio is beneath a predefined threshold, a calculation of the pre-distortion characteristic is not performed.

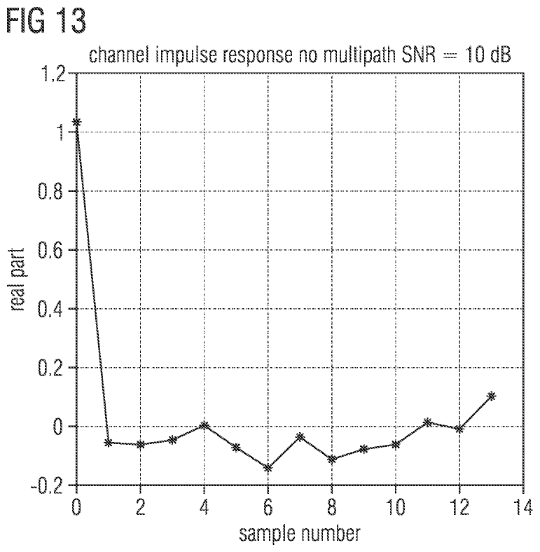

FIG. 13 illustrates a channel impulse response h of a transmission channel without multi-path signal propagation and a low signal-to-noise ratio SNR of 10 dB.

In a possible embodiment, the channel impulse response h can be calculated by a training sequence or test signal according to the minimum least square principle.

A received signal y can be formulated as follows:

y=A·h+w (1)

wherein y is the received signal vector of length N,
w is the noise signal vector of length N,
h is the channel impulse response vector of length L and
A is the matrix of complex training sequence symbols with size N×L.

The minimum least square solution is as follows:

$$\\ \begin{matrix}\hat{h} = avg {min}_{\hat{h}} {\sum }_{k = 0}^{N - 1} {\vert y ( k ) - {\sum }_{i = 0}^{L - 1} \hat{h} ( i ) \cdot a ( k - i ) \vert}^{2} & ( 2 )\end{matrix}$$

$$\\ \begin{matrix}{\hat{h} ( {A}^{{}_{} H} A )}^{- 1} {A}^{{}_{} H} y & ( 3 )\end{matrix}$$

wherein a training sequence can be chosen in such a way that it fulfills the condition:

A^{H}A=N·I_{L} (4)

In this case, the calculation of the channel impulse response h is simplified to the following matrix multiplication:

ĥ=A^{H}·y (5)

The channel impulse response h of the test signal received by the receiver of another apparatus 1B of the wireless network is determined by multiplication of a vector y of the received test signal with a matrix A comprising complex symbols of the test signal. The channel impulse response h calculated by matrix multiplication can be evaluated to derive metrics M representing the quality of the received test signal. Only if the metrics M indicate that the test signal received by the receiver comprises a sufficient quality, the pre-distortion characteristic is calculated by the processor 4B on the receiving side on the basis of the distorted ramp signal of the received test signal and on the basis of the known linear ramp signal.

In a possible embodiment, the transmission of the retransmission signal in step S5 of the method according to the present invention can be performed by the transmitter 3B of the test signal receiving second apparatus 1B having received the test signal of the wireless network with a time delay. The time-delayed transmission of the retransmission signal by the transmitter 3B of the test signal receiving second apparatus 1B of the wireless network allows a calibration or recalibration of the wireless network under control of an access layer of the respective wireless network. After having received and recognized the retransmission signal as directed to or as belonging to the first apparatus 1A, the first apparatus 1A having previously sent or broadcasted the associated test signal can store in a possible embodiment the pre-distortion characteristic extracted from the received retransmission signal in a local data memory. The stored pre-distortion characteristic can be then be used for performing a linearization of the transmission amplifier within the transmitter 2A by means of a pre-distortion unit of the first apparatus 1A in step S6 of the method according to the present invention.

The test signal and the retransmission signal can comprise in a possible implementation radio frequency, RF, signals. These signals can be sent in different channels or frequency bands or can be sent in different time slots.

FIG. 2 shows a block diagram for illustrating a possible exemplary embodiment of an apparatus according to a further aspect of the present invention. FIG. 2 illustrates the interaction of two similar apparatus 1 performing the method for linearizing a transmission amplifier according to the first aspect of the present invention. Apparatus 1A and apparatus 1B communicate with each other via a bidirectional communication or transmission channel. Apparatus 1A comprises a transmitter 2A and a receiver 3A. In the illustrated embodiment of FIG. 2, the first apparatus 1A further comprises a processing unit 4A. Apparatus 1B comprises in the illustrated embodiment of FIG. 2 a transmitter 2B, a receiver 3B and a processing unit 4B. Apparatus 1A and 1B form part of a wireless network.

In the illustrated schematic diagram of FIG. 2, the transmitter 2A of apparatus 1A sends a test signal via the bidirectional transmission channel to the receiver 3B of the other apparatus 1B. The transmitted test signal comprises a preamble and a ramp signal. The receiver 3B of apparatus 1B is adapted to receive the test signal. A received test signal can be processed by a processing unit 4B of the apparatus 1B to identify the transmitter of the transmitted test signal, for instance on the basis of the processed preamble of the test signal or on the basis of another processed identifier included in the test signal.

In a further step, the processing unit 4B of the apparatus 1B calculates a pre-distortion characteristic of the transmission amplifier within the transmitter 2A of apparatus 1A on the basis of the distorted ramp signal within the received test signal taking into account the known ideal non-distorted ramp signal. In a possible embodiment the calculation of the pre-distortion characteristic is performed by the processing unit 4B of the apparatus 1B only if quality metrics M of the received test signal indicate a sufficient quality of the received test signal.

In a further step, the transmitter 2B of apparatus 1B sends a retransmission signal back to apparatus 1A through the bidirectional transmission channel. The receiver 3A of apparatus 1A is adapted to receive the retransmission signal from the transmitter 3B of apparatus 1B of the wireless network. The retransmission signal transmitted by the transmitter 3B of apparatus 1B to the receiver 3A of apparatus 1A can also comprise a preamble. The transmission signal transports the pre-distortion characteristic of the transmission amplifier within the transmitter 2A of the first apparatus 1A having been calculated by the processing unit 4B of the second apparatus 1B. The transported pre-distortion characteristic can be extracted and then stored in a possible implementation in a local data memory of the first apparatus 1A. The stored pre-distortion characteristic and can be used for linearizing the transmission amplifier of the transmitter 2A of the first apparatus 1A. The transmission amplifier of the transmitter 2A of the first apparatus 1A is linearized according to the pre-distortion characteristic being calculated by the processing unit 4B of the second apparatus 1B within the wireless network on the basis of the test signal transmitted by the transmitter 2A of the first apparatus 1A and having been transported back to the first apparatus 1A within the retransmission signal sent by the transmitter 3B of the second apparatus 1B to the receiver 3A of first apparatus 1A.

Apparatus 1A, 1B may form part of a wireless network comprising a plurality of similar apparatuses 1. In a possible embodiment, this wireless network may comprise a decentralized ad hoc network as also illustrated in FIG. 3. The wireless network illustrated in FIG. 3 can comprise a plurality of network nodes or apparatus 1 each having an integrated transmitter 2 and an integrated receiver 3. The nodes or devices within the wireless network shown in FIG. 3 are adapted to perform the method as illustrated in the flowchart of FIG. 1.

The apparatus 1 according to the present invention may also form part of other networks, in particular time-division multiplexing (TDM) networks or mobile telecommunication networks of different standards. In a possible embodiment, the apparatus 1 can also be integrated in a mobile device such as a vehicle.

The transmission of a test signal by an apparatus 1 can be triggered by the transmitting first apparatus 1A and/or by the receiving second apparatus 1B depending on the use case. A broadcasting of a test signal can also be performed in a test operation mode of an apparatus or a test operation mode of the whole wireless network, for instance after a set-up of the wireless network. In a possible embodiment, the test signal may also be transmitted periodically for readjustment or calibration of the transmission amplifiers.

The method according to the present invention has the advantage that it does not need the provision of additional hardware within a circuit or a device forming a node within a wireless network. The method can be performed for all devices or nodes which operate in a wireless network with complex modulation bi-directionally. The nodes of the network communicate bi-directionally through a bidirectional transmission channel allowing to transmit and receive signals used to exchange data. Each node within the wireless network can trigger the calculation of a pre-distortion characteristic by broadcasting or sending a specific test signal. The signal received by an apparatus 1 or node within the wireless network can be recognized as a test signal by its preamble. The preamble of the test signal comprises two functions, i.e. it allows to recognize that a received signal forms a test signal and it can be used for performing an estimation of a quality of the transmission channel based on the channel impulse response h. The preamble may also comprise information allowing to identify the test signal transmitting node within the wireless network. In a possible embodiment, the wireless network may comprise different nodes such as illustrated in FIGS. 2, 3 having similar resources. However, the method according to the present invention is not limited to such a use case. For instance, a test signal receiving apparatus 1B may not comprise sufficient processing resources to calculate a pre-distortion characteristic. In this case, the apparatus 1B may relay the received test signal to a third apparatus of the wireless network which comprises the necessary processing resources. A node or apparatus 1 within the wireless network comprises in a possible embodiment a transmitter 2, a receiver 3 and a processing unit 4 as shown in FIG. 2. The apparatus 1 can further comprise a local data storage for storing a received distortion characteristic employed by a pre-distortion unit of the apparatus 1 to perform a pre-distortion of a signal supplied to a transmission amplifier of the transmitter 2 of the respective apparatus 1. The node or apparatus 1 can be integrated in a mobile device such as a vehicle. The generation of a test signal can be performed in specific operation mode or can be triggered event driven, e.g. if an observed signal distortion of a received signal exceeds a predetermined level.

In the illustrated embodiment of FIG. 2, each apparatus 1 within the wireless network comprises a transmitter 2, a receiver 3 and a processing unit 4. The apparatus 1 may comprise further entities such as sensors providing measurement data. After having successfully linearized the characteristic of the transmission amplifier of the transmitter 2 on the basis of the pre-distortion characteristic, the apparatus 1 may switch from a test operation mode to a normal operation mode where data is transmitted from one apparatus of the wireless network to another apparatus of the wireless network.

In a further possible application of the method according to the present invention, an additional pre-distortion against AM/PM distortion can be performed. This distortion is performed to compensate phase distortions within the transmitter characteristics. In this embodiment, a phase of the received ramp signal bw(k) is taken into account for calculation of the pre-distortion characteristic dw(k).

1. A method for linearizing a transmission amplifier of a transmitter within a wireless network comprising the steps of:
transmitting a test signal which comprises a preamble and a ramp signal by the transmitter of the wireless network;
receiving the test signal transmitted by the transmitter of the wireless network by at least one receiver of the wireless network;
identifying the transmitter of the transmitted test signal by the at least one receiver of the wireless network on the basis of the preamble of the test signal received by the respective receiver of the wireless network;
calculating a pre-distortion characteristic of the transmission amplifier of the identified transmitter by the at least one receiver of the wireless network on the basis of the distorted ramp signal of the test signal received by the receiver of the wireless network;
transmitting a retransmission signal which comprises a preamble and the calculated pre-distortion characteristic of the transmission amplifier of the identified transmitter by the receiver of the wireless network to the identified transmitter of the wireless network; and
linearizing the transmission amplifier of the transmitter on the basis of the pre-distortion characteristic of the retransmission signal received by the transmitter of the wireless network from the receiver of the wireless network.

2. The method of claim 1 wherein the preamble of the test signal comprises information used to identify the transmitter by the receiver and used for calculating a channel response, in particular a channel impulse response, h, of a transmission channel between the transmitter and the receiver of the wireless network.

3. The method of claim 1 wherein the preamble of the distorted ramp signal of the test signal received by the receiver of the wireless network is sampled with an oversampling rate.

4. The method of claim 1 wherein the preamble and the ramp signal of the transmitted test signal comprise complex signals.

5. The method of claim 1 wherein the ramp signal of the test signal comprises a linear increasing ramp signal or a linear decreasing ramp signal.

6. The method of claim 5 wherein the linear increasing ramp signal of the transmitted test signal comprises a predefined number of symbols, k, comprising values between an initial value of zero and a final value of one divided by the square root of two (1/sqrt (2)).

7. The method of claim 1 wherein values, dw(k), of the pre-distortion characteristic are calculated by a processor connected to the receiver of the wireless network in response to values, aw(k), of a non-distorted linear ramp signal and depending on values, bw(k), of the distorted ramp signal within the test signal received by the receiver of the wireless network.

8. The method of claim 7 wherein the values of the non-distorted linear ramp signal, aw(k), are read from a data memory of the receiver of the wireless network.

9. The method of claim 7 wherein the values, bw(k), of the distorted ramp signal of the test signal received by the receiver of the wireless network are normalized to a maximum value.

10. The method of claim 7 wherein for determining the values, dw(k), of the pre-distortion characteristic until a predefined threshold value, S, (k<=S) the values, dw(k), of the pre-distortion characteristic are set to a value of one (dw(k)=1), and wherein from the predefined threshold value, S, (k>S) on absolute values, abs(bw(k)), of the symbols, k, of the distorted ramp signal are divided by absolute values, abs(aw(k)), of the symbols, k, of the linear not distorted ramp signal to calculate the values, dw(k), of the pre-distortion characteristic.

11. The method of claim 10 wherein for linearizing the transmission amplifier each sample value, s(k), of a complex input signal supplied to the transmission amplifier of said transmitter are multiplied with a value, dw(n), of the pre-distortion characteristic, wherein the index, n, of the value of the pre-distortion characteristic used for multiplication is determined depending on the absolute value of the respective sample value, s(k), of the complex input signal supplied to the transmission amplifier and depending on a scaling factor, P.

12. The method of claim 1 wherein the test signal transmitted by the transmitter of the wireless network comprises guard time intervals before and after the linear ramp signal included in the transmitted test signal.

13. The method of claim 1 wherein at least one metric, M, is determined which represents the quality of the test signal received by the receiver of the wireless network.

14. The method of claim 13 wherein the at least one metric, M, representing the quality of the received test signal is determined on the basis of a calculated channel response, in particular a channel impulse response, of the test signal received by the receiver of the wireless network.

15. The method of claim 13 wherein a first metric, M1, represents the quality of the test signal received by the receiver of the wireless network with respect to multi-path signal propagation and wherein a second metric, M2, represents the quality of the test signal received by the receiver of the wireless network with respect to a signal to noise ratio, SNR.

16. The method of claim 15 wherein the pre-distortion characteristic of the transmission amplifier of the identified transmitter is calculated by the at least one receiver of the wireless network on the basis of the distorted ramp signal of the test signal received by the receiver if both determined metrics, M1, M2, indicate a sufficient quality of the test signal received by the receiver of the wireless network.

17. The method of claim 15 wherein a multi-path signal propagation of the transmitted test signal is determined on the basis of spurious signal pulses within the test signal received by the receiver of the wireless network.

18. The method of claim 15 wherein the signal to noise ratio, SNR, of the test signal received by the receiver of the wireless network is determined by division of amplitudes of spurious signal pulses of the channel response of the received test signal by the amplitude of a main pulse of the channel response of the received test signal.

19. The method of claim 14 wherein the channel impulse response of the test signal received by the receiver of the wireless network is determined by multiplication of a vector, y, of the received test signal with a matrix, A, comprising complex symbols of the test signal.

20. The method of claim 19 wherein the transmission of the retransmission signal is performed by the receiver of the wireless network with a time delay.

21. The method of claim 20 wherein by the time-delayed transmission of the retransmission signal by the receiver of the wireless network a calibration of the wireless network is performed under control of an access layer of the wireless network.

22. The method of claim 1 wherein the calculated pre-distortion characteristic included in the retransmission signal is stored in a data memory of the transmitter of the respective wireless network.

23. An apparatus for signal transmission within a wireless network comprising:
a transmitter adapted to transmit a transmission signal amplified by a transmission amplifier of the transmitter to a receiver of at least one other apparatus within the respective wireless network;
a receiver adapted to receive a retransmission signal from a transmitter of another apparatus of the wireless network;
wherein the transmission amplifier of the transmitter of the apparatus is linearized according to a pre-distortion characteristic which is calculated by a processor of another apparatus of the wireless network on the basis of a test signal transmitted by the transmitter of the apparatus, wherein the calculated pre-distortion characteristic is transported within a retransmission signal received by the receiver of the respective apparatus from the other apparatus of the wireless network.

24. A wireless network comprising a plurality of apparatuses for signal transmission within a wireless network adapted to exchange signals via a bidirectional transmission channel, wherein at least one apparatus for signal transmission within a wireless network comprising
a transmitter adapted to transmit a transmission signal amplified by a transmission amplifier of the transmitter to a receiver of at least one other apparatus within the respective wireless network;
a receiver adapted to receive a retransmission signal from a transmitter of another apparatus of the wireless network;
wherein the transmission amplifier of the transmitter of the apparatus is linearized according to a pre-distortion characteristic which is calculated by a processor of another apparatus of the wireless network on the basis of a test signal transmitted by the transmitter of the apparatus, wherein the calculated pre-distortion characteristic is transported within a retransmission signal received by the receiver of the respective apparatus from the other apparatus of the wireless network.

25. The wireless network of claim 24 wherein the wireless network comprises a decentralized ad hoc network.

26. The wireless network of claim 24 wherein the wireless network comprises a mobile telecommunication network.
